(19) United States
(12) Patent Application Publication
(10) Pub. No.: US 2026/0271762 A1
(43) Pub. Date: Sep. 10, 2026

(54) METHOD FOR FORMING BUMPS ON SUBSTRATE

(71) Applicant: Skytech Inc., Hsinchu County (TW)

(72) Inventors: CHI-HSIANG LIU, Hsinchu County (TW); YAO-SYUAN CHENG, Hsinchu County (TW); KUO-JU LIU, Hsinchu County (TW); CHING-LIANG YI, Hsinchu County (TW)

(21) Appl. No.: 19/202,248

(22) Filed: May 8, 2025

(30) Foreign Application Priority Data
Mar. 5, 2025 (TW) 114108190

(51) Int. Cl. H01L 23/00

(52) U.S. Cl. CPC H10W 72/012; H10W 72/019; H10W 72/20; H10W 72/90; H10W 72/01238; H10W 72/01953; H10W 72/252; H10W 72/923; H10W 72/952

(57) ABSTRACT

The disclosure is a method for forming bumps on a substrate, comprising the following steps: providing a substrate, wherein a surface of the substrate has at least one recess; forming a first metal layer on the surface of the substrate and filling the recess on the substrate with the first metal layer; forming a second metal layer on the first metal layer; forming a bump on a partial area of the second metal layer; performing a plasma etching on the second metal layer not covered by the bump; and removing the first metal layer not covered by the bump and the first metal layer located in the recess through an etching solution. The method is able to effectively remove the metal within the recess of the substrate, thereby mitigating the risk of bump structure damage during the etching process.

### CROSS-REFERENCE TO RELATED APPLICATIONS

This non-provisional application claims priority claim under 35 U.S.C. § 119(a) on Taiwan Patent Application No. 114108190 filed Mar. 5, 2025, the entire contents of which are incorporated herein by reference.

### TECHNICAL FIELD

This disclosure relates to a method for forming bumps on a substrate, which is able to effectively remove the metal within the recesses of the substrate, thereby mitigating the risk of bump structure damage during the etching process.

### BACKGROUND

Flip-chip packaging refers to a semiconductor packaging technique wherein a semiconductor die is inverted such that its solder bumps are aligned and bonded directly to corresponding pads on a substrate. In contrast to conventional wire-bond packaging, flip-chip technology offers advantages including increased interconnect density, reduced signal latency, enhanced thermal performance, and miniaturized package dimensions.

Within a flip-chip packaging, the bump interconnects formed on the semiconductor die function as miniature bridges, facilitating a direct and robust connection between the die and the external substrate. This arrangement enables the semiconductor die to interface with external circuitry or other chips via the substrate, thereby enabling its intended operational functionality.

The manufacturing method of bumps mainly includes processes such as thin film deposition, photolithographic patterning (exposure and development), and etching, to form bumps on partial areas of semiconductor die.

In practical applications, an under-bump metallurgy (UBM) is usually placed between the bump and the semiconductor die. The primary function of the UBM is to ensure the reliability of the electrical connection between the semiconductor die and the bump, and to improve the overall reliability of the package. In addition, the UBM can also be used to block the mutual diffusion of materials between the semiconductor die and the bump, so as to avoid affecting the performance of the semiconductor die.

Despite their diminutive size, bump interconnects and UBM are integral components in semiconductor packaging. As the semiconductor industry advances, the technologies associated with bumps and UBM are continually evolving to address the growing complexity of electronic device requirements.

### SUMMARY

This disclosure provides a method for forming bumps on a substrate, particularly applicable to a method for forming bumps and under-bump metallurgy (UBM) on a substrate having at least one recess. Through the manufacturing method of the invention, the metal within the recesses of the substrate can be effectively removed, and damage to the bump structures formed on the substrate during the etching process can be avoided.

An objective of the invention is to provide a method for forming bumps on a substrate. First, a first conductive layer or a hole-filling layer is formed on the surface of the substrate and in the recesses, thereby establishing a planarized surface for subsequent deposition of a second conductive layer. Subsequently, a second conductive layer and the first conductive layer are etched in two stages through plasma and etching solution, respectively, which can reduce the damage to the bumps during the process of removing the second conductive layer and the first conductive layer, and is beneficial to maintain the integrity of the bump structure.

An objective of the invention is to provide a method for forming bumps on a substrate. First, a patterned photoresist is formed on specific positions of the substrate to define and reserve the positions for subsequent bump formation. Subsequently, a hole-filling layer is formed on the surface of the substrate where the patterned photoresist is not formed, wherein the hole-filling layer can be used to fill the recesses on the substrate. A first conductive layer is formed on the hole-filling layer with better flatness, and a second conductive layer is formed on the first conductive layer. Through the formation of the patterned photoresist, the bumps and the substrate or metal pads will not have the thick hole-filling layer between them, which is beneficial to reduce the impedance between the bumps and the substrate or metal pads.

To achieve the foregoing objectives, this disclosure provides a method for forming bumps on a substrate, comprising: providing a substrate, wherein a surface of the substrate has at least one recess; forming a first metal layer on the surface and in the recess of the substrate; forming a second metal layer on the first metal layer; forming at least one bump on a partial area of the second metal layer; using a plasma to remove the second metal layer not covered by the bump; and using an etching solution to remove the first metal layer not covered by the bump, and the first metal layer located in the recess.

This disclosure provides another method for forming bumps on a substrate, comprising: providing a substrate, wherein a surface of the substrate has at least one recess; forming at least one patterned photoresist on a partial surface of the substrate; forming a hole-filling layer on the surface and in the recess of the substrate; removing the patterned photoresist formed on the substrate to form at least one exposed portion on the substrate; forming a first metal layer on the hole-filling layer and the exposed portion; forming a second metal layer on the first metal layer; forming at least one bump on a partial area of the second metal layer; using a plasma to remove the second metal layer not covered by the bump; using the plasma or a first etching solution to remove the first metal layer not covered by the bump; and using a second etching solution to remove the hole-filling layer not covered by the bump, and the hole-filling layer located in the recess.

The method for forming bumps on a substrate according to the invention has the following advantages: it can effectively remove the metal located in the recesses of the substrate and can avoid damaging the bump structures on the substrate during the etching process.

### BRIEF DESCRIPTION OF THE DRAWINGS

FIG. 1 to FIG. 4 are cross-sectional views of a manufacturing process of a method for forming bumps on a substrate according to an embodiment of the invention.

FIG. 5 to FIG. 10 are cross-sectional views of a manufacturing process of a method for forming bumps on a substrate according to another embodiment of the invention.

### DETAILED DESCRIPTION

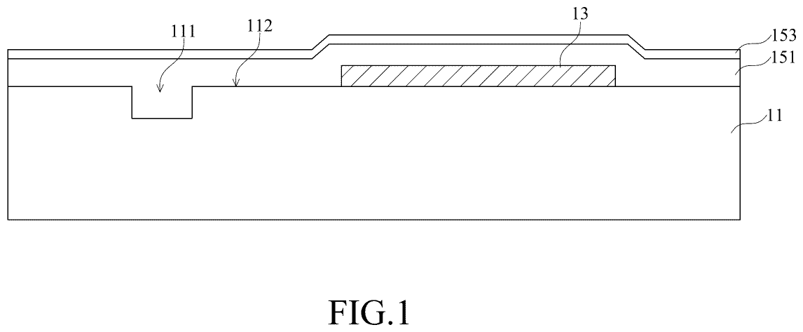

FIG. 1 to FIG. 4 are cross-sectional views of a manufacturing process of a method for forming bumps on a substrate according to an embodiment of the invention. First, a substrate 11 is provided, wherein a surface 112 of the substrate 11 has at least one recess 111. For example, the recess 111 may be a groove or a hole.

In one embodiment of the invention, the substrate 11 may be a semiconductor substrate used for manufacturing semiconductor devices, such as a silicon substrate, a silicon germanium substrate, a sapphire substrate, a silicon carbide substrate, a gallium arsenide substrate, or a silicon-on-insulator (SOI) substrate, etc. At least one semiconductor device (not shown) may be formed inside or on the surface of the substrate 11. For example, the semiconductor device may be various forms of transistors, resistors, diodes, capacitors, or inductors, etc.

In addition, an interconnect structure (not shown) may be formed on the substrate 11, wherein the interconnect structure includes metal wires and vias, and is electrically connected to the semiconductor devices. The aforementioned semiconductor devices and interconnect structure are not the focus of the invention, and thus are not drawn in detail in the figures.

At least one metal pad 13 is formed on a partial area of the substrate 11, wherein the metal pad 13 can be connected to the semiconductor devices through the interconnect structure. For example, the metal pad 13 may include aluminum, copper, silver, gold, nickel, tungsten, or alloys of the aforementioned materials. The metal pad 13 may be a single-layer or multi-layer structure.

As shown in FIG. 1, a first metal layer 151 is formed on a surface 112 of the substrate 11 and in the recess 111. The surface 112 of the substrate 11 has the recess 111 and/or the metal pad 13, and the first metal layer 151 covers the recess 111 and the metal pad 13 formed on the surface 112. Specifically, the first metal layer 151 is located in the recess 111 of the substrate 11 and is used to fill the recess 111, so that the first metal layer 151 located above the recess 111 and the surface 112 of the substrate 11 has a similar height or flatness. For example, the thickness of the first metal layer 151 may be greater than or equal to the depth of the recess 111.

In one embodiment of the invention, after the formation of the first metal layer 151, a planarization process may be performed on the first metal layer 151 to make the surface of the first metal layer 151 smoother.

In practical applications, the first metal layer 151 may be formed on the surface 112 of the substrate 11 using a physical vapor deposition process or a chemical vapor deposition process. In one embodiment of the invention, the first metal layer 151 includes, but is not limited to, titanium, titanium alloy, tungsten alloy, or alloy of titanium and tungsten.

Before forming the first metal layer 151 on the surface 112 of the substrate 11, the substrate 11 is usually thoroughly cleaned to remove impurities such as organic matter and oxides remaining on the surface 112 of the substrate 11, to ensure good adhesion between the first metal layer 151 and the substrate 11.

After the formation of the first metal layer 151, a second metal layer 153 can be formed on the first metal layer 151. In practical applications, the second metal layer 153 may be formed on the surface of the first metal layer 151 using the physical vapor deposition process or the chemical vapor deposition process. In one embodiment of the invention, the second metal layer 153 includes, but is not limited to, gold or gold alloy.

Since the first metal layer 151 fills the recesses 111 on the surface 112 of the substrate 11, the second metal layer 153 can be formed on the first metal layer 151 with higher flatness.

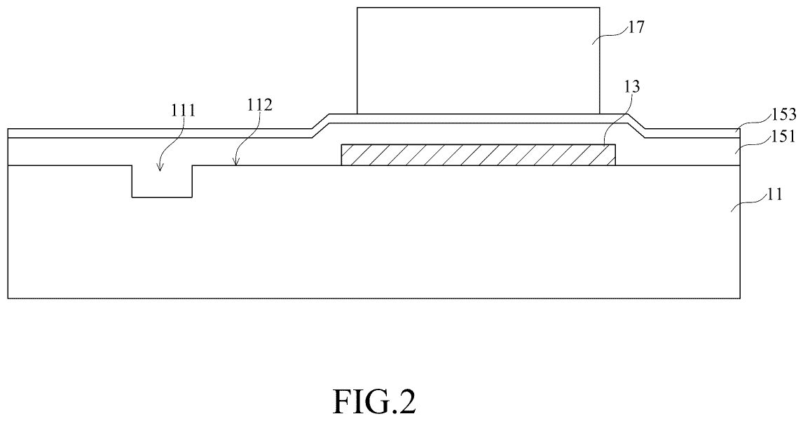

As shown in FIG. 2, at least one bump 17 is formed on a partial area of the second metal layer 153. In one embodiment of the invention, the placement of the bump 17 may coincide with the location of the metal pad 13. For example, the bump 17 may be formed above the metal pad 13, wherein the stacked first metal layer 151 and second metal layer 153 are between the bump 17 and the metal pad 13.

In practical applications, a patterned photoresist can be formed on a partial area of the second metal layer 153 using photolithographic techniques, to define the forming position and pattern of the bump 17 on the second metal layer 153. For example, the surface of the second metal layer 153 located above the metal pad 13 is not formed with the patterned photoresist. Then, the bump 17 is formed on the second metal layer 153 without the patterned photoresist through the deposition process. For example, the bump 17 may be formed on the surface of the second metal layer 153 not covered by the photoresist through chemical vapor deposition, physical vapor deposition, or electroplating. After the formation of the bump 17 is completed, the patterned photoresist on the second metal layer 153 can be removed.

According to the requirements of the process, the material for fabricating the bump 17 may include materials such as tin alloy, gold, copper alloy, nickel, and silver. Among them, the bump 17 made of gold has advantages such as excellent conductivity, corrosion resistance, high stability, and low contact resistance, and is therefore widely used in high-frequency and high-speed components, high-reliability products, and driver circuits. However, the gold bump 17 also has disadvantages such as high cost, easy cracking, and relatively difficult soldering.

In order to improve the disadvantages of the gold bump 17, in one embodiment of the invention, it is proposed to use a silver-gold alloy to fabricate the bump 17, which can significantly reduce the fabrication cost of the bump 17 without affecting too much of the performance of the bump 17. For example, the weight percentage of silver in the bump 17 can be between 30% and 90%.

After the formation of the bump 17 is completed, the second metal layer 153 and the first metal layer 151 not covered by the bump 17 can be removed.

When simply using an etching solution to etch the second metal layer 153 and/or the first metal layer 151 not covered by the bump 17, the etching solution used to etch the second metal layer 153 may damage the structure of the bump 17. For example, when the bump 17 includes the silver-gold alloy and the second metal layer 153 is gold or a gold alloy, if aqua regia or potassium iodide is used to etch the second metal layer 153, the silver in the bump 17 will be etched simultaneously, and a plurality of holes or voids will be formed on the bump 17. This not only causes the structure of the bump 17 to be unstable, but also may reduce the conductivity of the bump 17.

Conversely, if plasma is simply used to remove the second metal layer 153 and/or the first metal layer 151 not covered by the bump 17, although it will not cause too much damage to the structure of the bump 17, such as not forming holes on the bump 17. However, the plasma may not achieve complete removal of the second metal layer 153 and/or the first metal layer 151 located in the recess 111. For example, the plasma may be blocked by the recess 111.

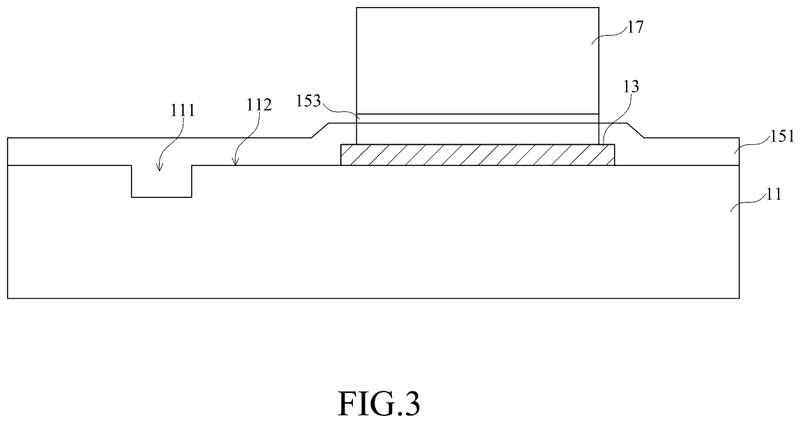

To address this, the invention further proposes, as shown in FIG. 3, to use plasma to remove the second metal layer 153 not covered by the bump 17, for example, to use inductively coupled plasma (ICP) to remove the second metal layer 153 not overlapping with the bump 17.

Since the first metal layer 151 is formed on the surface 112 of the substrate 11 before the second metal layer 153 is formed, wherein the first metal layer 151 is located in the recess 111 of the substrate 11 to fill the recess 113 and form a relatively flat first metal layer 151 on the surface 112 of the substrate 11. Therefore, the second metal layer 153 is formed on the relatively flat first metal layer 151. For example, the surface of the first metal layer 151 does not have depressions or protrusions, and plasma can be used to completely remove the second metal layer 153 not covered by the bump 17.

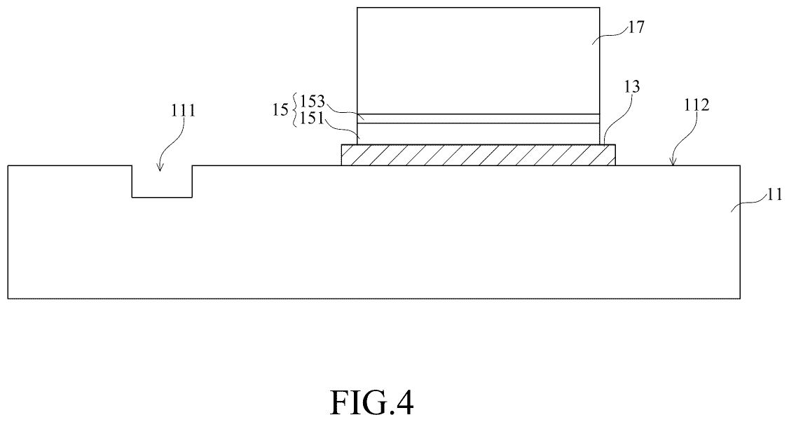

As shown in FIG. 4, after removing the second metal layer 153, the first metal layer 151 not covered by the bump 17 can be removed by an etching solution, wherein the etching solution can completely remove the first metal layer 151 located on the surface 112 of the substrate 11 and in the recess 111.

In practical applications, an appropriate etching solution can be selected according to the material of the first metal layer 151. For example, when the material of the first metal layer 151 is titanium, titanium alloy, or titanium tungsten alloy, hydrofluoric acid, hydrofluoric acid and hydrogen peroxide, or hydrofluoric acid and nitric acid can be used to etch the first metal layer 151. The etching solution used to etch the first metal layer 151 will not etch the bump 17 made of gold-silver alloy, and can maintain the structural integrity and conductivity of the bump 17.

In addition, through the two-stage etching steps, the etching time of the etching solution can be reduced, which is beneficial to reduce the interaction time between the etching solution and the first metal layer 151 located below the bump 17, to avoid severe undercutting around the first metal layer 151 below the bump 17.

After completing the two-stage etching steps, the step of forming the bump 17 on the substrate 11 is completed, wherein only the stacked first metal layer 151 and the second metal layer 153 exist between the bump 17 and the substrate 11. The stacked first metal layer 151 and the second metal layer 153 below the bump 17 can be defined as under-bump metal (UBM) 15, which serves to enhance the reliability of the electrical interconnection between the substrate 11 and the bump structure 17, and to mitigate material interdiffusion between the substrate 11 and the bump structure 17.

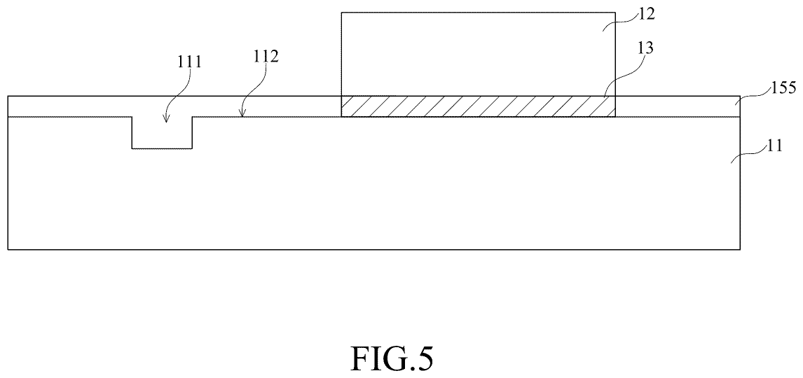

FIG. 5 to FIG. 10 are cross-sectional views of a manufacturing process of a method for forming bumps on a substrate according to another embodiment of the invention. First, a substrate 11 is provided, wherein a surface 112 of the substrate 11 has at least one recess 111. For example, the recess 111 may be a groove or a hole.

In practical applications, when the depth of the recess 111 on the substrate 11 is large, the thickness of the first metal layer 151 used to fill the recess 111 in FIG. 1 also increases, resulting in an increase in the thickness of the first metal layer 151 between the bump 17 and the metal pad 13 in FIG. 4, which may cause an increase in the impedance between the bump 17 and the metal pad 13.

In addition, when the thickness of the first metal layer 151 is large, the etching time of the etching solution used to etch the first metal layer 151 also increases to completely remove the first metal layer 151 on the surface 112 of the substrate 11 and in the recess 111. As a result, the interaction time between the etching solution and the first metal layer 151 located below the bump 17 also increases, which may cause severe undercutting around the first metal layer 151 below the bump 17. If the area of the undercutting is too large, it will cause the line width to be smaller than the expected line width, and may weaken the bonding between the bump 17 and the metal pad 13, thereby reducing the reliability of subsequent products.

In order to avoid the occurrence of the above problems, another method for forming bumps 17 on a substrate 11 is provide in this embodiment of the invention. As shown in FIG. 5, at least one patterned photoresist 12 is formed on a partial surface 112 of the substrate 11. In one embodiment of the invention, the surface 112 of the substrate 11 has a metal pad 13, and the patterned photoresist 12 can be formed on the metal pad 13 of the substrate 11. For example, the patterned photoresist 12 can be formed on the surface of the metal pad 13 through an exposure and development process.

Subsequently, a hole-filling layer 155 is formed on the surface 112 of the substrate 11. The surface 112 of the substrate 11 has a recess 111, and the hole-filling layer 155 is formed on the surface 112 of the substrate 11 not covered by the patterned photoresist 12, and covers the recess 111 of the substrate 11. For example, the thickness of the hole-filling layer 155 may be greater than or equal to the depth of the recess 111. Specifically, the hole-filling layer 155 is located in the recess 111 of the substrate 11 and is used to fill the recess 111, wherein the hole-filling layer 155 located above the recess 111 and the surface 112 of the substrate 11 has a similar height or flatness. In one embodiment of the invention, after the formation of the hole-filling layer 155 is completed, a planarization process may be further performed on the hole-filling layer 155 to make the surface of the hole-filling layer 155 relatively flat.

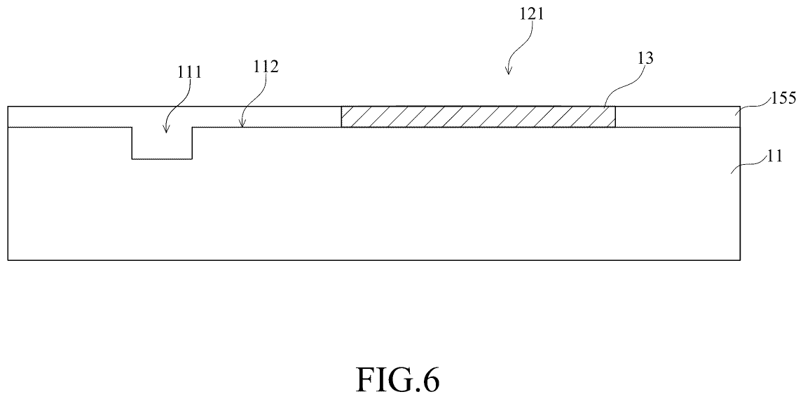

As shown in FIG. 6, the patterned photoresist 12 formed on the substrate 11 is removed, and at least one exposed portion 121 is formed on the substrate 11. For example, after removing the patterned photoresist 12, the metal pad 13 originally masked by the patterned photoresist 12 is exposed.

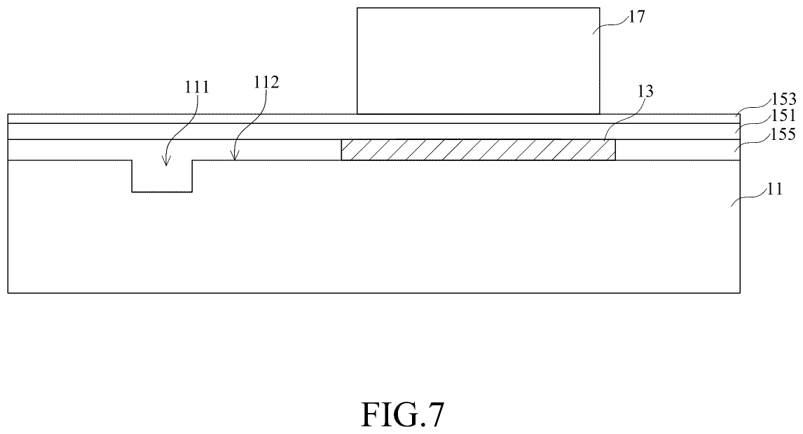

As shown in FIG. 7, a first metal layer 151 is formed on the hole-filling layer 155 and the exposed portion 121. For example, the first metal layer 151 covers the hole-filling layer 155 and the metal pad 13.

Subsequently, a second metal layer 153 is formed on the first metal layer 151. In practical applications, the hole-filling layer 155, the first metal layer 151, and the second metal layer 153 may be formed using the physical vapor deposition process or the chemical vapor deposition process. For example, the material of the first metal layer 151 includes, but is not limited to, titanium, titanium alloy, tungsten alloy, or titanium tungsten alloy, the material of the second metal layer 153 includes, but is not limited to, gold or gold alloy, and the material of the hole-filling layer 155 includes titanium, titanium alloy, tungsten alloy, tungsten alloy, aluminum, aluminum alloy, or aluminum copper alloy.

After completing the formation of the first metal layer 151 and the second metal layer 153, at least one bump 17 is formed on a partial area of the second metal layer 153. In one embodiment of the invention, the forming position of the bump 17 can overlap with the metal pad 13 and the exposed portion 121. For example, the bump 17 can be formed above the metal pad 13, wherein the stacked first metal layer 151 and the second metal layer 153 are between the bump 17 and the metal pad 13.

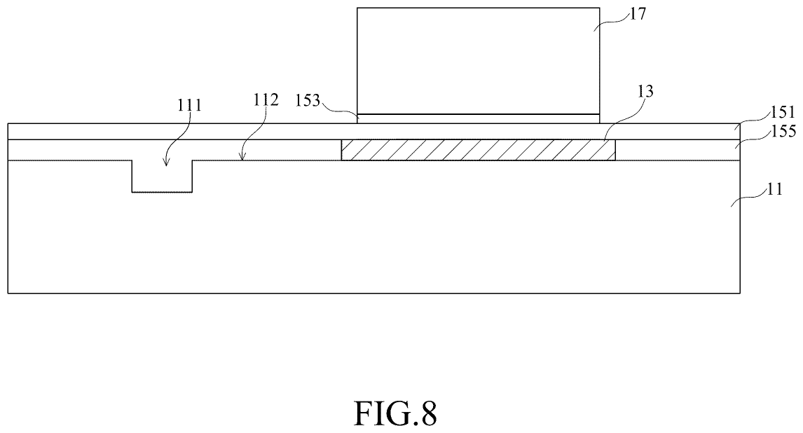

As shown in FIG. 8, the second metal layer 153 not covered by the bump 17 is removed using plasma. For example, the second metal layer 153 not overlapping with the bump 17 is removed using inductively coupled plasma (ICP).

Since the first metal layer 151 and the second metal layer 153 are formed on the relatively flat hole-filling layer 155, for example, the surface of the first metal layer 151 does not have depressions or protrusions. Thus, plasma can be used to completely remove the second metal layer 153 not covered by the bump 17.

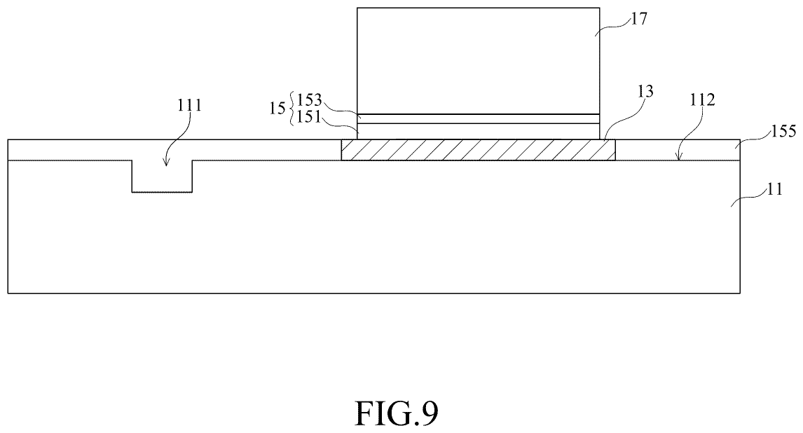

As shown in FIG. 9, after removing the second metal layer 153, the first metal layer 151 not covered by the bump 17 may be removed by a first etching solution. In other embodiments, since the first metal layer 151 is formed on the relatively flat hole-filling layer 155, plasma can also be used to completely remove the first metal layer 151 not covered by the bump 17.

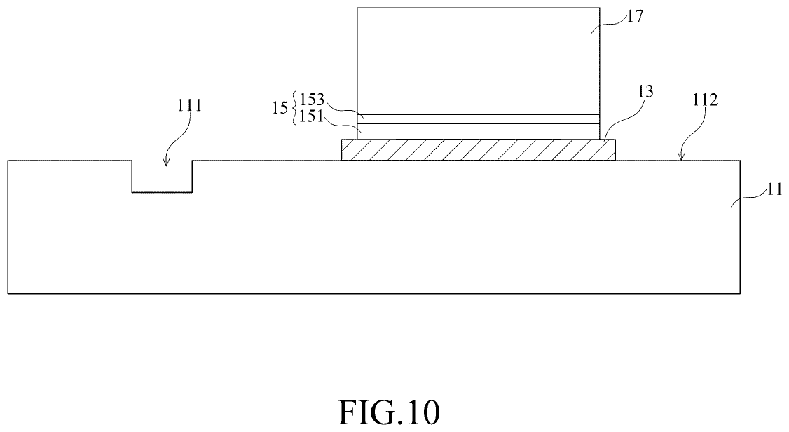

As shown in FIG. 10, after removing the first metal layer 151, the hole-filling layer 155 not covered by the bump 17 can be removed by a second etching solution, wherein the second etching solution can completely remove the hole-filling layer 155 located on the surface 112 of the substrate 11 and within the recess 111. In practical applications, if the materials of the first metal layer 151 and the hole-filling layer 155 are the same or similar, the first etching solution and the second etching solution may be the same chemical solution.

Through the manufacturing method described in the embodiments of the invention, neither the excessively thick first metal layer 151 nor the hole-filling layer 155 will be generated between the bump 17 and the metal pad 13 and/or the substrate 11, thereby preventing an increase in the impedance between the bump 17 and the metal pad 13.

In practical applications, the first metal layer 151 and the hole-filling layer 155 may be different materials, wherein the second etching solution used to etch the hole-filling layer 155 may not etch the first metal layer 151, or has a lower etching rate for the first metal layer 151. This can avoid severe undercutting around the first metal layer 151 between the bump 17 and the metal pad 13, which is beneficial to improve the stability of the connection between the bump 17 and the metal pad 13, and increase the reliability of subsequent products.

Compared to the manufacturing method of FIG. 1 to FIG. 4, the bump 17 and the under-bump metal 15 produced by the manufacturing method described in FIG. 5 to FIG. 10 have better conductivity characteristics, but require the addition of at least one photolithography process step and the use of at least one photomask, which will inevitably increase the manufacturing cost. In practical applications, users can choose one of the above methods to form the under-bump metal 15 and the bump 17 on the substrate 11 according to the product requirements or the depth of the recess 111 on the substrate 11.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A method for forming bumps on a substrate, comprising:
providing a substrate, wherein a surface of the substrate has at least one recess;
forming a first metal layer on the surface and in the recess of the substrate;
forming a second metal layer on the first metal layer;
forming at least one bump on a partial area of the second metal layer;
using a plasma to remove the second metal layer not covered by the bump; and
using an etching solution to remove the first metal layer not covered by the bump, and the first metal layer located in the recess.

2. The method for forming bumps on a glass substrate as claim 1, wherein the bump comprise an alloy of silver and gold.

3. The method for forming bumps on a glass substrate as claim 2, wherein the first metal layer comprises titanium, titanium alloy, tungsten alloy, or titanium-tungsten alloy.

4. The method for forming bumps on a glass substrate as claim 3, wherein the second metal layer comprises gold or gold alloy.

5. The method for forming bumps on a glass substrate as claim 1, further comprising:
forming at least one metal pad on the substrate; and
forming the bump above the metal pad, wherein the bump overlaps with the metal pad.

6. The method for forming bumps on a glass substrate as claim 1, further comprising:
planarizing the first metallic layer, and then forming the second metal layer on the first metal layer.

7. A method for forming bumps on a substrate, comprising:
providing a substrate, wherein a surface of the substrate has at least one recess;
forming at least one patterned photoresist on a partial surface of the substrate;
forming a hole-filling layer on the surface and in the recess of the substrate;
removing the patterned photoresist formed on the substrate to form at least one exposed portion on the substrate;
forming a first metal layer on the hole-filling layer and the exposed portion;
forming a second metal layer on the first metal layer;
forming at least one bump on a partial area of the second metal layer;
using a plasma to remove the second metal layer not covered by the bump;
using a first etching solution to remove the first metal layer not covered by the bump; and
using a second etching solution to remove the hole-filling layer not covered by the bump, and the hole-filling layer located in the recess.

8. The method for forming bumps on a glass substrate as claim 7, wherein the bump comprises alloy of silver and gold.

9. The method for forming bumps on a glass substrate as claim 8, wherein the first metal layer comprises titanium, titanium alloy, tungsten alloy, or titanium-tungsten alloy.

10. The method for forming bumps on a glass substrate as claim 9, wherein the second metal layer comprises gold or gold alloy.

11. The method for forming bumps on a glass substrate as claim 7, further comprising:
forming at least one metal pad on the substrate; and
forming the patterned photoresist above the metal pad, wherein the patterned photoresist overlaps with the metal pad.

12. The method for forming bumps on a glass substrate as claim 11, further comprising:
removing the patterned photoresist formed above the metal pad to form the exposed portion on the substrate, wherein the exposed portion overlaps with the metal pad.

13. The method for forming bumps on a glass substrate as claim 12, further comprising:
forming the bump above the exposed portion, wherein the bump overlaps with the exposed portion and the metal pad.

14. The method for forming bumps on a glass substrate as claim 7, further comprising: planarizing the hole-filling layer, and then forming the first metal layer on the hole-filling layer.

15. A method for forming bumps on a substrate, comprising:
providing a substrate, wherein a surface of the substrate has at least one recess;
forming at least one patterned photoresist on a partial surface of the substrate;
forming a hole-filling layer on the surface and in the recess of the substrate;
removing the patterned photoresist formed on the substrate to form at least one exposed portion on the substrate;
forming a first metal layer on the hole-filling layer and the exposed portion;
forming a second metal layer on the first metal layer;
forming at least one bump on a partial area of the second metal layer;
using a plasma to remove the second metal layer and the first metal layer not covered by the bump; and
using an etching solution to remove the hole-filling layer not covered by the bump, and the hole-filling layer located in the recess.

16. The method for forming bumps on a glass substrate as claim 15, further comprising: planarizing the hole-filling layer, and then forming the first metal layer on the hole-filling layer.
